(19) United States
(12) Patent Application Publication
(10) Pub. No.: US 2006/0142968 A1
(43) Pub. Date: Jun. 29, 2006

(54) Home control system using galvanic skin response and heart rate and method thereof

(75) Inventors: Dae-ho Han, Seoul (KR); Youn-ho Kim, Hwaseong-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/305,187

(22) Filed: Dec. 19, 2005

(30) Foreign Application Priority Data
Dec. 29, 2004 (KR) 2004-115182

(51) Int. Cl. G01R 27/28

(52) U.S. Cl. 702/120

(57) ABSTRACT

A home control system using galvanic skin responses and heart rate information and a method thereof. Whether a user is awake is judged using a galvanic skin response sensor, and the extent of stress of a user is determined using the user's heart rate, thereby extracting a user's emotional state and sleeping state. Furthermore, based on these, various systems in the home network of a user are controlled according to the user's emotional state and sleeping state. In addition, those control results are stored in a database so as to create the optimum control conditions.

### CROSS-REFERENCE TO RELATED APPLICATIONS

This application claims priority under 35 U.S.C. § 119 from Korean Patent Application No. 2004-115182, field on Dec. 29, 2004, the entire content of which is incorporated herein by reference.

### BACKGROUND OF THE INVENTION

1. Field of the Invention

Systems and methods consistent with the present invention relate to home control using galvanic skin response and heart rate information, and more specifically, to control of optimum sleeping environments and home facilities in accordance with a user's state using heart rate and galvanic skin response information.

2. Description of the Related Art

Due to advancements in networks and advancements in sensor and control systems, there has been much progress in the automation and intelligence of the home and housekeeping affairs. In addition to home shopping and home banking systems, there are major home control systems such as a home security system for preventing crimes and disasters, a house control system for controlling electricity and gas, automated metering, automatic cooking facilities, and the like, and an energy control system for controlling energy, lighting, cooling and heating, and hot water supply.

For example, a number of services can be performed automatically through a system and network installed inside a home, such as: turning on the switches at a predetermined time in order to operate video tape recorders or cassette tape recorders or to secure doors and windows; controlling room temperature or water temperature of a bathtub; and preventing a gas leak.

Such advancements in technology may also be applied to checking a user's mental state and condition and to providing optimum sleeping or home environments thereby.

Electroencephalography (EEG) is typically used in order to determine a subject's sleeping state. The subject's sleeping state can be identified as within one of four stages using an EEG

In addition, even while sleeping, a subject may be under stress due to aspects of her sleeping environment such as dampness and heat, and this stress can be measured using an EEG.

However, conventionally, there is no home system that can integrate and control such functions as a whole in order to measure the sleeping state of a subject and to help the subject get an optimal rest or a sound sleep, such as a system capable of controlling temperature, humidity, illumination, and the like.

In addition, in a case in which a brainwave analyzer is used in order to analyze a subject's sleeping stages, to the subject must wear brainwave measurement equipment while sleeping. Likewise, additional measurement equipment must be attached to the user's wrists and ankles in order to measure stress while sleeping, so that a subject is inconvenienced by wearing such equipment while sleeping.

Therefore, a system and method for unifying and controlling home systems which utilize measurements of a subject's galvanic skin responses and heart rate has become necessary.

### SUMMARY OF THE INVENTION

The present invention provides a home control system using galvanic skin response and heart rate information and a method thereof, which classify a user's state based on the user's galvanic skin responses and heart rate, build a database of a user's behavioral patterns according to the classification and analyze a sleeping user's optimum sleeping environments using the database in order to create the optimum sleeping environments by controlling home facilities, and provide the optimal programming when a user is watching television.

According to one aspect of the invention, there is provided a home control system comprising a user monitor for periodically outputting the user information of at least one user including whether a user is in a waking state judged by galvanic skin responses and a stress index determined by the change of the heart rate, a home server for storing the periodically received user information in a database and outputting a facility control command based on the database, and a home facility system for receiving the facility control command in order to control the environments of at least one user inside the home.

Furthermore, the home control system further comprises a sensor system for outputting home state information including at least one of the temperature, humidity, and illumination inside a home to the home server according to a request of the home server, and a network for connecting the home server, health monitor, sensor system, and home facility system.

The home server stores the sleep information and the home state information amongst the user information within the database, the sleep information including a sleeping user's sleeping stage information classified according to galvanic skin response and stress index, and creates sleeping environments for each sleeping stage. The home facility system receives the facility control command according to the sleeping environments of at least one user and controls any one of the temperature, humidity, and illumination inside the home.

Preferably, the network is a wireless network, specifically a wireless LAN (WLAN) or a Wireless Personal Area Network (WPAN).

The home server calculates an average value of the home state information in each sleeping stage and judges the sleeping environment, the average value being calculated in a case where the stress index is less than a predetermined value using the sleep information and the home state information that is stored in the database for more than a certain period of time.

The home server includes a database for storing the sleep information and the home state information. In addition, the database preferably stores control result information including the sleeping stage, stress index, home state information, and received time in one unit.

In addition, the average values are the averages of the temperature, humidity, and illumination of the control result information having a stress index less than a predetermined value, the control result information being extracted from the control result information sorted by the sleeping stage, and the output of the facility control command is used for controlling the home facility system so that the home state information according to the sleeping stage becomes the average value.

The output of the facility control command is maintained so long as the sleeping stage is not changed.

The ratio of the average value that is calculated for an initial certain period of time to the values that is measured after that initial certain period of time is calculated, the value being the galvanic skin response measured as a resistance value, and the sleeping stage is divided into a certain number of stages.

In addition, the Heart Rate Variability (HRV) is measured from the maximum peak interval of the R wave or the photoplethysmography (PPG) among electrocardiogram waves, and the stress index is calculated by applying the HRV to the frequency conversion analysis.

The sensor system includes a sensor controller connected to the network for outputting the home state information according to the request of the home server and at least one sensor for measuring any one of the temperature, humidity, and illumination of a user's sleeping space and outputting it to the sensor controller.

In addition, the home facility system includes at least one air conditioner for controlling the temperature and humidity of the air of the user's sleeping space according to the facility control command of the home server, at least one boiler for controlling the floor temperature of the user's sleeping space according to the facility control command of the home server, and at least one lighting facility for controlling the illumination of the user's sleeping space according to the facility control command of the home server.

The sleeping environment control system of the invention further comprises an aroma injector for injecting aromas into the user's sleeping space in order to decrease the stress according to an injection command from the home server, the injection being performed in a case where the stress index is more than a predetermined value.

Accordingly, when a user's predetermined wake-up time arrives, the home server sends a command to the aroma injector for injecting an aroma having a stimulant composition.

According to another embodiment of the invention, the user information includes a user's emotional state classified into certain stages on the basis of whether a user is in a waking state and the stress index, and the home facility system provides digital television (TV) broadcast signals, certain information on the broadcast signals, image signals, and voice signals according to the facility control command.

In this case, the home facility system includes a tuner for receiving the digital TV broadcast signals including Electric Program Guide (EPG) signals, i.e. information on the program that is being broadcasted, a set-top box for outputting the EPG signals according to the request of the home server, receiving the facility control command including the EPG user interface (UI) that is broadcast program information recommended based on the emotional state, and inserting the EPG UI into the broadcast signals, and a digital TV for displaying the EPG UI and the broadcast signals to the user according to the broadcast signals decrypted and output from the set-top box.

At the point of receiving the emotional state, the home server stores the genre of the broadcast that the user is watching and the emotional state in the database, wherein the keyword representing the broadcast genre of the Description that is the detailed information of each program included in the EPG signals is searched, thereby classifying the broadcast genre.

The EPG UI is the information on the broadcast program, amongst the broadcast programs that are extracted from the EPG signals and for broadcast after the extraction, whose genre is identical to the genre of the broadcast program that is most stored in the emotional state, from amongst all the broadcast genres in the database.

In addition, the digital TV receives a selection command for any one of the broadcast programs included in the output EPG UI, outputs the corresponding selection information to the set-top box, and outputs the broadcast of the broadcast channel changed by the set-top box based on the selection information.

According to another embodiment of the invention, the home control method comprises periodically receiving user information including whether a user is in a waking state judged by galvanic skin responses and the stress index determined by the change in heart rate, storing the periodically received user information in a database, and controlling the environment inside the user's home by outputting a facility control command based on the database in order to control at least any one of the temperature, humidity, and illumination inside a home or by providing TV broadcast information.

In this case, the user information is sleep information including the sleeping user's sleeping stage information classified according to the galvanic skin response and the stress index. In the storing, after receiving the sleep information, the home state information including at least any one of the temperature, humidity, and illumination inside a home is requested, received, and stored in the database together with the sleep information on the basis of the received time. In the controlling, the user's sleeping environments in each sleeping stage are judged, and the facility control command is output.

In the controlling, an average value of the home state information in each sleeping stage is calculated, the average value being calculated in a case where the stress index is less than a predetermined value using the sleep information and the home state information that is stored in the database for more than a certain period of time, and the sleeping environment is judged.

The database stores control result information including the sleeping stage, stress index, home state information, and received time in one unit.

In addition, the average values are the averages of the temperature, humidity, and illumination of the control result information having the stress index less than the predetermined value, the control result information being extracted from the control result information sorted by sleeping stage, and the output of the facility control command is used for controlling the home facility system so that the home state information according to the sleeping stage becomes the average value.

The output of the facility control command is maintained so long as the sleeping stage is not changed.

In addition, the home control method of the invention further comprises injecting aromas into the user's sleeping space in order to decrease the stress, the injection being performed in a case where the stress index is more than a predetermined value or injecting an aroma having a stimulant composition when the user's predetermined wake-up time arrives.

The controlling includes receiving the digital broadcast signals including Electric Program Guide (EPG) signals, i.e. information on the program that is being broadcasted, receiving the facility control command including the EPG UI that is broadcast program information recommended based on the emotional state and inserting the EPG UI into the broadcast signals, and outputting the EPG UI and image signals to the user according to the decrypted broadcast signals.

At the point of receiving the emotional state, the genre of the broadcast that the user is watching and the emotional state can be stored in the database on the basis of the receiving point.

The keyword representing the broadcast genre of the Description that is the detailed information of each program included in the EPG signals is searched, thereby classifying the broadcast genre.

The EPG UI is the information on the broadcast program, from amongst the broadcast programs that are extracted from the EPG signals and for broadcast after the extraction, whose genre is identical to the genre of the broadcast program that is most stored in the emotional state, from amongst the genres in the database, and, in the outputting the EPG UI and the broadcast signals, a selection command for any one of the broadcast programs included in the output EPG UI is received, and the broadcast channel changed based on the selection information can be output.

### BRIEF DESCRIPTION OF THE DRAWINGS

The above and/or other aspects of the present invention will become more apparent by the following detailed description of exemplary embodiments of the present invention with reference to the accompanying drawings, in which:

FIG. 1 is a block diagram of a sleeping environment control system based on sleeping stages according to an exemplary embodiment of the invention;

FIG. 2 is a graph showing a frequency spectrum of a heart rate variability;

FIG. 3 shows a control result information table stored in a database;

FIG. 4 shows an example of a record in the first sleeping stage extracted from the control result information table;

FIG. 5 is a flowchart explaining the operation of storing the control result information of the sleeping environment control system of an exemplary embodiment of the invention;

FIG. 6 is a flowchart explaining the operation of analyzing and creating sleeping environments of the sleeping environment control system of an exemplary embodiment of the invention;

FIG. 7 is a flowchart explaining the operation of a control method of an aroma injector of the sleeping environment control system of the an exemplary embodiment of invention;

FIG. 8 is a block diagram of a broadcast information providing system according to an exemplary embodiment of the invention;

FIG. 9 shows an example of an EPG UI that can be displayed on a digital TV according to the exemplary broadcast information providing system depicted in FIG. 8; and

FIG. 10 is a flowchart explaining the operation of a broadcast information providing system according to an exemplary embodiment of the invention.

### DETAILED DESCRIPTION OF THE EXEMPLARY EMBODIMENTS

Exemplary embodiments of the present invention will be described in greater detail with reference to the accompanying drawings.

A home control system according to an exemplary embodiment of the present invention determines a user's state based on galvanic skin response and heart rate information. Information relating to the user's state is stored in a database. The system provides an optimum sleeping environment and broadcast programs based on the user's behavioral patterns which are determined based on the stored information. Hereafter, an exemplary sleeping environment control system and an exemplary broadcast information providing system are explained separately.

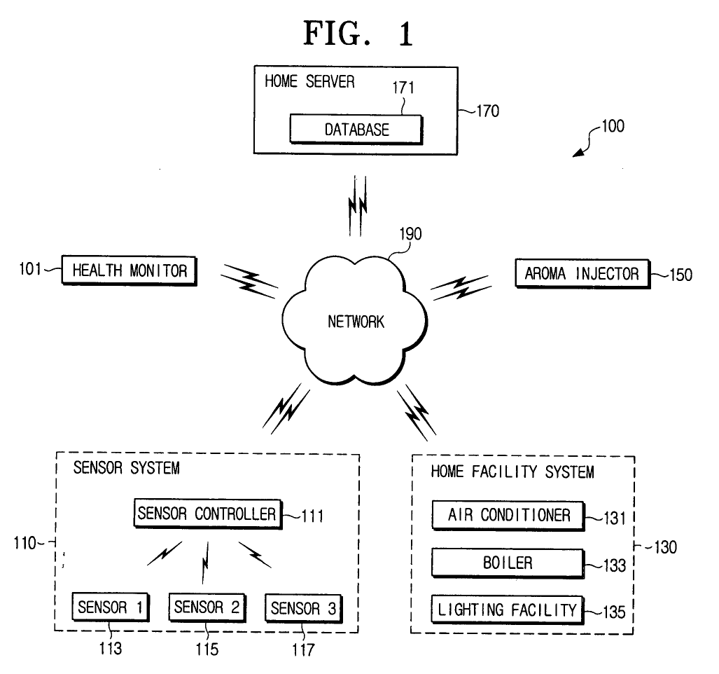

FIG. 1 is a block diagram of a sleeping environment control system based on sleeping stages according to an exemplary embodiment of the invention.

A sleeping environment control system 100 controls various devices inside a home so that a user can maintain an optimum sleeping state. In addition, the sleeping environment control system 100 is an intelligent system that stores control result information in a database in order to track, manage, and learn information related to a user's sleep and sleep patterns, thereby enabling the system to prepare the optimum sleeping environments in accordance with the user's sleeping stage.

The sleeping environment control system 100 of this embodiment includes a health monitor 101, a sensor system 110, a home facilities system 130, an aroma injector 150, and a home server 170, all of which are interconnected through a network 190.

The sleeping environment control system 100 of the invention can manage information relating to a user's sleeping stages and stress (“sleep information”), as measured through the health monitor 101, and the information relating to temperature, illumination, and humidity (“home state information”) inside a home, as measured through the sensor system 110. The sleep information and home state information are v stored in the database 171 on the home server 170.

The sleeping environment control system 100 analyzes the optimum sleeping environments for a user's current sleeping stage based on the information stored in the database. The sleeping environment control system 100 controls the home facilities system 130 based on the analyzed sleeping environments in order to create home environments for a user.

In addition, the sleeping environment control system 100 can be connected to a network (not shown) outside of a home, e.g. the Internet, in order to be connected to an external device (not shown). A hospital system and an emergency rescue system, or the like are non-limiting examples of such an external device (not shown).

Hereafter, elements of the sleeping environment control system 100 of this exemplary embodiment are explained with reference to FIG. 1.

The network 190 included in the sleeping environment control system 100 of the invention may include a wired network and/or a wireless network, or a combination thereof. An exemplary wireless network includes a wireless LAN and a wireless personal area network (WPAN). In addition, Bluetooth, Zigbee, or ultra wide band (UWB) communications technologies, or a combination thereof, can be used.

The health monitor 101 monitor's a user's sleep information and periodically transfers the information to the home server 170 through the network 190. As explained above, the sleep information includes the user's sleeping stages and the user's sleeping stress information determined from the user's sleeping heart rate. The health monitor 101 can be conveniently attached to a wrist or an ankle of a user who is going to sleep, which may greatly reduce the physical annoyance that might otherwise impose on a user's sleep.

The health monitor 101 may include a wired interface as well as a wireless interface (not shown) that can be connected to the network 190.

The health monitor 101 uses a galvanic skin response (GSR) sensor in order to determine a user's sleeping state. The GSR sensor is used for measuring the skin's resistance against electric stimulus and can be used to predict the emotional state and unconscious feelings of the user. Strain or stimulus increases the humidity of the skin due to increased sweat, thus decreasing the electric resistance of the skin by increasing electric conductivity. Low skin resistance indicates strain, and high skin resistance indicates relaxation.

An average value of skin resistance, measured over a predetermined time period after a user begins wearing the health monitor, is used as a reference value. The health monitor 101 then determines the user's sleeping stage based on a value calculated by dividing the measured skin resistance value by the reference value (hereafter, referred to as the GSR Normalization (GN)). The predetermined time for calculating the reference value may be five minutes beginning when a user first starts operating the sleeping environment control system 100 and wearing the health monitor 101.

The health monitor 101 can classify a user's sleeping stage using the GN value, and may classify it as within one of four stages, ranging from a first sleeping stage to a fourth sleeping stage. However, the number of sleeping stages is not limited to four.

The first sleeping stage is a waking state prior to sleeping. The second sleeping stage is a drowsy state prior to sleeping. The third sleeping stage is an unconscious state prior to a deep sleep. The fourth sleeping stage is a deep sleeping state in a sound sleep.

The four sleeping stages can be determined as shown in Table 1, below.

TABLE 1

| Sleeping Stage | Range of GN value | User's sleeping state |
|---|---|---|
| First stage | GN Value ≦ 1.2 | Waking state |
| Second stage | 1.2 < GN value ≦ 1.5 | Drowsy state |
| Third stage | 1.5 < GN value ≦ 2.0 | Light sleeping state |
| Fourth stage | 2.0 < GN value | Deep sleeping state |

The health monitor 101 periodically transmits the measured sleeping stages to the home server 170 through the network 190.

In order to determine a sleeping user's stress, the health monitor 101 calculates the maximum peak interval of the R wave or of the photoplethysmography (PPG), from among the measured electrocardiogram waves, in order to determine the Heart Rate Variability (HRV). The monitor then analyzes the frequency spectrum through frequency conversion analysis in order to determine an indexed value of a user's stress (“stress index”). The health monitor 101 periodically transmits the user's stress index to the home server 170.

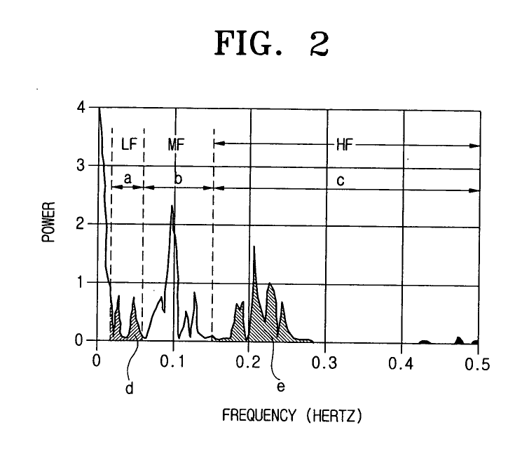

An exemplary method of calculating the stress index is explained in detail below with reference to FIG. 2.

FIG. 2 is a graph showing a frequency spectrum of heart rate variability.

Referring to FIG. 2, the horizontal axis of the graph represents frequency in Hertz (Hz), and the vertical axis represents HRV power in an energy unit.

The frequency band of the frequency spectrum of the HRV in FIG. 2 is separated into a low frequency band (LF) a, a middle frequency band (MF) b, and a high frequency band (HF) c. The health monitor determines the user's stress based on the frequency spectrum in each spectrum area.

In FIG. 2, the low frequency band a is between 0.001 and 0.05 Hz, the middle frequency band b is between 0.05 and 0.15 Hz, and the high frequency band c is between 0.15 and 0.5 Hz.

In FIG. 2, if the spectrum area d, of the low frequency band a, increases, stress increases according to the increase of the sympathetic nerve system. If the spectrum area e, of the high frequency band c, increases, stress decreases according to the increase of the para-sympathetic nerve system.

The health monitor 101 calculates the ratio of the spectrum area d of the low frequency band a to the spectrum area e of the high frequency band in order to calculate the stress index of each state. The state may be indexed based on the extremely stressed state of 100.

In another exemplary embodiment of the invention, the measured HRV power and the signal of the galvanic skin response sensor is used in order to determine the stress index in percentages.

Returning to the explanation of FIG. 1, the sensor system 110 transfers the home state information (including the temperature, humidity, and illumination of the space where a user is sleeping) to the home server 170 through the network 190 in response to a request from the home server 170. The sensor system 110 includes a sensor controller 111 and various sensors 113, 115, and 117.

The sensor controller 111 periodically receives information regarding the ambient temperature, floor temperature, humidity, and illumination of the space where a user is sleeping from the sensors 113, 115, and 117. The sensor controller 111 then creates home state information and transmits the home state information to the home server 170 through the network 190.

The sensor controller 111 includes a wired interface or a wireless interface (not shown) which connects the sensor controller 111 to the network 190.

The sensors 113, 115, and 117 may correspond to a temperature sensor, a humidity sensor, and an optical sensor respectively. The sensors 113, 115, and 117 are connected to the sensor controller 111 through a wired connection or a wireless connection and periodically transmit the current temperature, humidity, and illumination to the sensor controller 111.

In another exemplary embodiment of the invention, the sensors 113, 115, and 117 are connected to the home server 170 through a wired network or a wireless network (not shown), and transfer the measured temperature, humidity, and illumination to the home server 170 according to a request from the home server 170. In this case, the sensor controller 111 can be excluded from the configuration of the invention.

The home facility system 130 controls the airflow, temperature, humidity, and illumination inside of a home based on a facility control command from the home server 170. The home facility system 130 may include an air conditioner 131, a boiler 133, and a lighting facility 135.

The air conditioner 131 maintains the temperature, humidity, cleanliness, and average current flow of air within a room suitable for sleeping and exhausts dust, harmful gas, and the like from the room. The air conditioner 131 is connected to the home server 170 through the network 170, and operates based on a facility control command from the home server 170.

The boiler 133 is connected to the home server 170 through the network 190, and controls the floor temperature and the room temperature of the room where a user is sleeping based on a facility control command from the home server 170.

The lighting facility 135 is connected to the home server 170 through the network 190, and controls the illumination of the room where a user is sleeping based on a facility control command from the home server 170.

In another exemplary embodiment of the invention, the home facility system 130 includes a home facility controller (not shown). The home facility controller (not shown), which corresponds to a Programmable Logic Controller (PLC), can be connected to the home server 170 through the network 190, and controls the air conditioner 131, boiler 133, and lighting facility 135 based on a facility control command from the home server 170 in order to adjust the temperature, humidity, and illumination inside of a home. According to this exemplary embodiment, the air conditioner 131, boiler 133, and lighting facility 135 do not need to have an interface in order to be connected to the network 190, and are connected to the home facility controller (not shown) through a wired network or a wireless network (not shown).

The PLC is a digital electronic controller in which the functions of conventional relay, timer, counter, and the like are performed by semiconductor elements, which can store commands and program execution commands of the control algorithm. The commands enable the performance of special functions such as logic, operation, calculation, and sequential processing for controlling various kinds of machines and facilities.

The aroma injector 150 is connected to the network 190 and injects aromas into the air where a user is sleeping based on an injection command from the home server 170. The injected aroma may include lavender, menthol, or other various aromas used in aromatherapy. The home server 170 may reduce the stress index of a sleeper through the user of aromas, and, if a predetermined time to wake up or an alarm time is set, the home server can use an aroma such as menthol in order to help awaken a sleeper.

The home server 170 is connected to the network 190 controls the sleeping environment control system 100, and maintains an optimum sleeping environment based on a plurality of users' sleeping stages. The home server 170 may be embodied in a separate dedicated device, or may be embodied in programs capable of controlling the home server 170 of the invention using a personal computer.

The home server 170 creates a home environment, and stores information in the database for a certain period of time. The information includes a user's sleep information and home state information based on the home environment.

The home server 170 analyzes optimum sleeping environments suitable for the user's current sleeping stage based on information stored in the control result information database, and outputs a facility control command to the home facility system 130 according to the result of the analysis in order to create an optimum sleeping environment for the user. Furthermore, if the stress index of a sleeping user is high, the aroma injector 150 sends a command for injecting an appropriate aroma in order to decrease the stress index of the sleeper.

In addition, the home server 170 can be connected to an external device (not shown) through a network (not shown) outside of a home. For example, if the home server 170 is aware that there is an emergency, it can connect to an external emergency rescue system (not shown) and request help.

The home server 170 includes a database 171. However, the database 171 can be provided separately outside of the home server 170.

In addition, the home server 170 can include a user interface (not shown). The user interface (not shown) receives user commands and displays the current control states including the currently home environment to a user.

The user interface (not shown) can receive operation commands and operation cancel commands from a user for the sleeping environment control system 100. Each user can connect to the home server 170 using a separate user identification, so that a user may control only a specific room or a specific space inside of a home.

The user interface (not shown) can receive instructions from a user for a wake-up time or for a time to shut-off an alarm. The home server 170 can inject an aroma such as menthol when a set time arrives, and can thereby wake up a user.

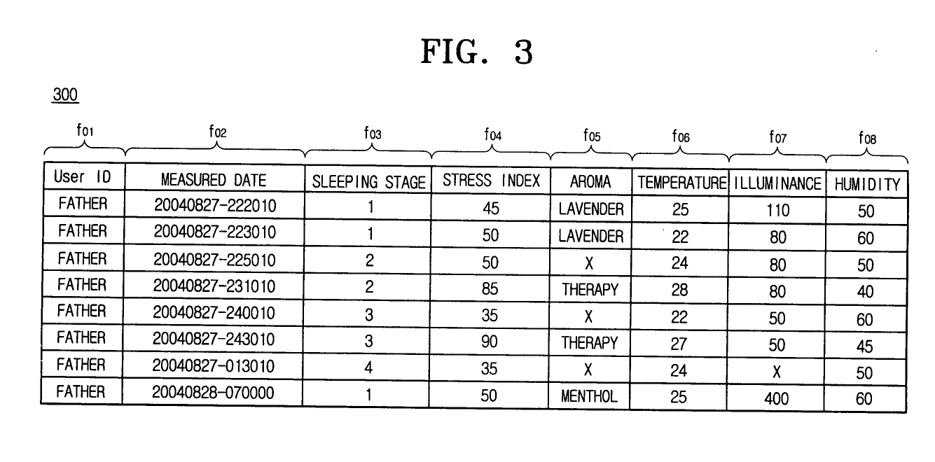

Hereafter, an exemplary method performed in a home server 170 for storing control result information in a database and for controlling the home facility system 130 based on that database is explained with reference to FIGS. 3 to 7.

The home server 170 stores the control result information in the control result information table of the database 171. The control result information integrates the sleep information periodically received from the health monitor 101 with the home state information when receiving the home state information from the sensor system 110.

FIG. 3 shows an exemplary control result information table stored in a database.

Referring to FIG. 3, the control result information table 300 stored in the database 171 includes at least one record including information in the exemplary fields of user identification f01, measured date f12, sleeping stage f03, stress index f04, aroma f05, temperature f06, illumination f17, and humidity f18.

The user identification field f01 stores information regarding the current user, and the measured date field f02 stores information regarding the time when the sleep information and the home state information are received. The sleeping stage field f03 and the stress index field f04 store a user's sleeping stage and a stress index received from the health monitor 101.

The aroma field f05 stores information regarding the aroma injected according to the aroma therapy. The aroma is injected when a user's sleeping stage is 1, when the stress index is bigger than a first reference value, and when a predetermined wake-up time has arrived. The first reference value may be a stress index of 70.

The temperature field f06, illumination field f07, and humidity field f08 store information regarding the temperature, illumination, and humidity requested from the sensor controller 111 and received as a response on the measured date.

The home server 170 analyzes the sleeping environments and determines an optimum sleeping environments for each sleeping stage based on the control result information of a predetermined period that is stored in the control result information table 300 of the database 171. The home server then outputs a facility control command to the home facility system 130.

In the analysis of the sleeping environments, only the records having a value in the stress index f04 less than a second reference value for each sleeping stage f03 are extracted, the record being stored in the control result information table 300 for a predetermined period of time, and the averages of the values of the temperature field f06, the illumination field f07, and the humidity field f08 of the extracted records are calculated in order to be set as the optimum environments of each sleeping stage. The second reference value may be the stress index value of 30.

The predetermined period of time for the analysis of the sleeping environments can be set to a week or a month.

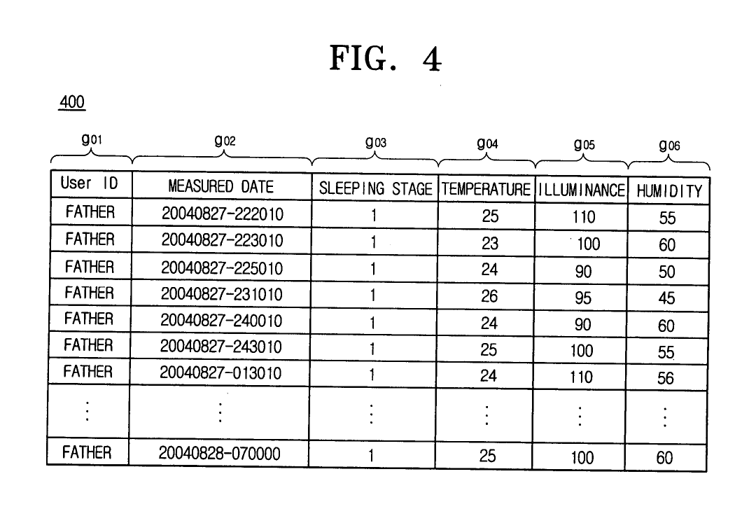

FIG. 4 shows an example of a record in the first sleeping stage extracted from the control result information table.

The records 400 depicted in FIG. 4 are only those records having a value in the stress value field f04 of less than the second reference value, the records being extracted from the control result information table 300, and a value in the stress index field f04 of less than 30.

A user identification field g01, a measured date field g02, a sleeping stage field g03, a temperature field g04, an illumination field g05, and a humidity field g06 correspond to the identification field f01, the measured date field f02, the sleeping stage field f03, the temperature field f06, the illumination field f07, and the humidity field f08 of the control result information table 300 of FIG. 3.

The home server 170 calculates averages for the values in the temperature field g04, the illumination field g05, and the humidity field g06 of at least one record 400 extracted as shown in FIG. 4 respectively, sets them as the optimum sleeping environments for the first sleeping stage, and outputs a facility control command including the set value to the home facility system 130, thereby controlling the temperature, illumination, and humidity inside of a home.

The home server 170 may analyze the sleeping environments from the control result information table 300 stored for at least a month.

Accordingly, the first week after the sleeping environment control system 100 of the invention has been constructed is established as the ‘user sleep analysis operation’, and the home facility system 130 is not automatically controlled. During this period, the sleep information and the home state information are stored in the control result information table 300 of the database 171. After the ‘user sleep analysis operation’ of the first week, the records having values in the stress index field f04 less than the second reference value are retrieved as shown in FIG. 4, and the optimum sleeping environments are analyzed, thereby enabling the control of the home facility system 130. After a month, the optimum sleeping environments may be analyzed again from the control result information table 300 for that month, and the home facility system 130 may be controlled based on the new environments.

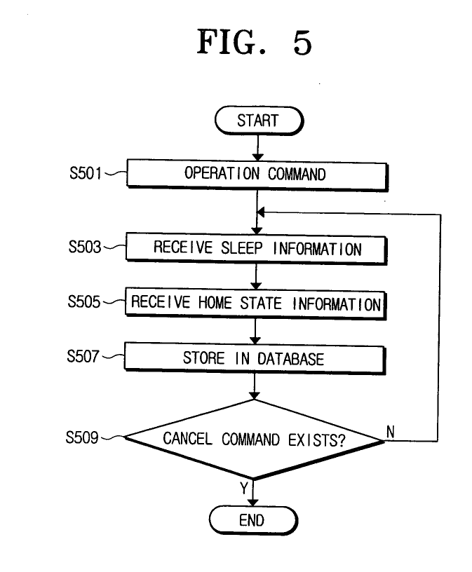

FIG. 5 is a flowchart explaining the operation of storing the control result information of the sleeping environment control system of the invention.

Referring to FIGS. 1 to 5, the operation of storing the control result information of the sleeping environment control system of the invention is explained.

When the home server 170 receives a user's operation command through the user interface (not shown) (S501), the home server receives sleep information from the health monitor 101 in a certain time interval (S503).

On receiving sleep information from the health monitor 101, the home server 170 requests home state information from the sensor controller 111, and the sensor controller 111 receives the current home state information from the sensors 1 to 3 113, 115, 117, and transfers it to the home server 170 (S505).

The home server 170 stores the received sleep information and home state information together with the received time in the control result information table 300 of the database 171 (S507).

The home server 170 determines whether there is a cancel command from the user (S509), and if there is not a cancel command, the home server repeats the operations S503 to S507 in order to store the control result information.

According to the method described above, the sleeping environment control system 100 of the invention stores a user's sleep information and home state information in a database, and determines the optimum sleeping environment for the user based on the information in the database.

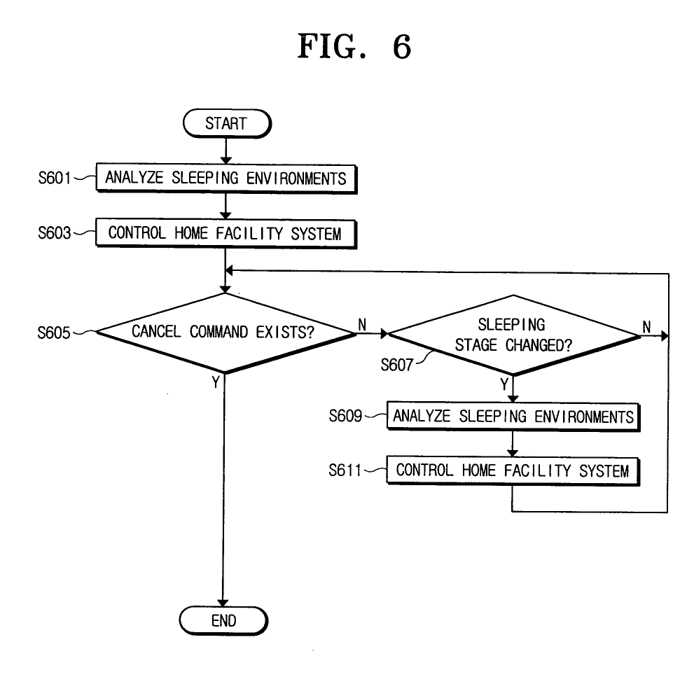

FIG. 6 is a flowchart explaining the operation of analyzing and creating the sleeping environments of the sleeping environment control system of the invention.

Hereafter, referring to FIGS. 1 to 6, the operation of analyzing and creating the sleeping environments of the sleeping environment control system of the invention is explained.

When the sleeping environment control system 100 of the invention is in operation, the home server 170 extracts those records from the control result information table 300 of the database 171 which have values in the stress index field f04 less than the second reference value and which have a sleeping stage corresponding to the current sleeping stage received from the health monitor 101. For example, in the case of the record 400 in FIG. 4, if the current sleeping stage is the first stage, the home server 170 calculates the average values of the temperature field g04, the illumination field g05, and the humidity field g06 of the retrieved record 400, thereby determining the optimum sleeping environments for the first sleeping stage (S601).

The home server 170 outputs a facility control command to the air conditioner 131, boiler 133, and lighting facility 135 of the home facility system 130 according to the analyzed average value of the optimum sleeping environments, thereby creating the optimum sleeping environments (S603).

The home server 170 judges whether there is a cancel command from the user (S605). If there is not a cancel command, the home server 170 judges whether the sleeping stage has changed using the sleep information (S607).

If the sleeping stage has not changed, the home server 170 does not change but maintains the current facility control command on the home facility system 130 as is. However, if the sleeping user's stress index is more than the first reference value, the stress index can be decreased using the aroma injector 150.

If the sleeping stage has changed, for example, to the second sleeping stage, the home server 170 retrieves the records having values in the stress index field f04 less than the second reference value and having a sleeping stage corresponding to the current sleeping stage (i.e., the second sleeping stage) from the control result information table 300 in the same manner as in operation S601, and determines the optimum sleeping environments for the second sleeping stage (S609).

The home server 170 outputs a facility control command to the home facility system 130 based on the average value analyzed in accordance with the changed sleeping stage (S611).

The home server 170 repeats the operations S607 to S611 until a cancel command from operation is received at operation S605.

According to the method described above, control of the home facility control system 130 is accomplished.

Hereafter, an exemplary control method of the aroma injector of the sleeping environment control system 100 according to the invention is explained.

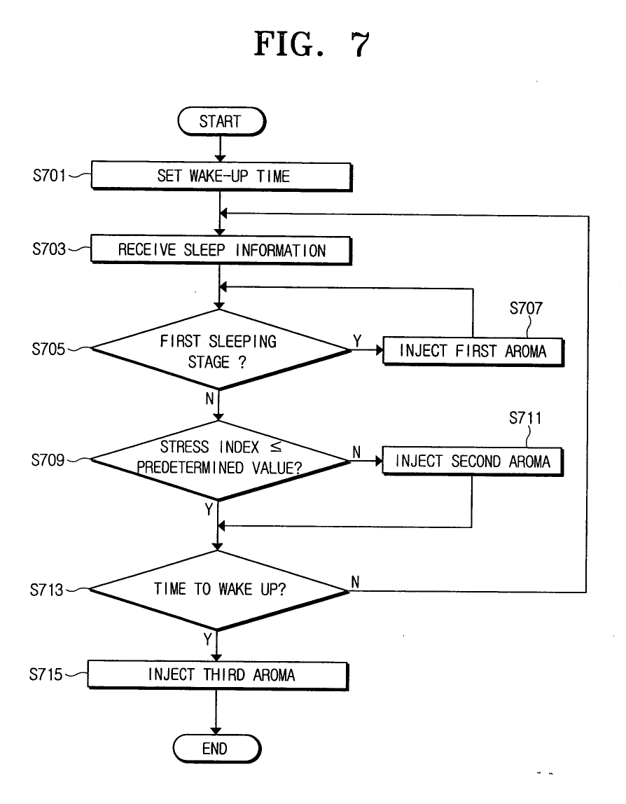

FIG. 7 is a flowchart explaining the operation of the control method of an exemplary aroma injector of the sleeping environment control system of the invention.

The home server 170 receives the setting of a wake-up time from a user through the user interface (not shown) (S701).

The home server 170 receives sleep information from the health monitor 101 (S703), and determines whether or not the sleeping stage is the first sleeping stage (S705).

If the sleeping stage is the first sleeping stage, the process of the home server 170 proceeds to operation S707. If the sleeping stage is the first sleeping stage, an injection command for the first aroma is output to the aroma injector 150 (S707). The aroma injector 150 injects the first aroma into the user's sleeping space according to the injection command. An aroma having a sedative effect for putting a user to sleep may be suitable for the first aroma, and lavender can be used. In addition, the first aroma may be injected at a regular time interval, and may be injected every 30 minutes (S707).

If the sleeping stage is not the first sleeping stage, the process of the home server 170 determines whether or not the stress index is less than a predetermined value (S709). The predetermined value may be the second reference value of 30.

If the stress index is not less than the second reference value, the home server 170 outputs an injection command to the aroma injector 150 for injecting the second aroma (S711). The second aroma is used for decreasing a user's stress index, and appropriate aromatherapy can be used. The injection of the second aroma may also be performed at a predetermined time interval (S711).

If the stress index is less than the second reference value, the home server 170 determines whether the preset wake-up time has arrived (S713), and if the wake-up time has arrived, an injection command for the third aroma is output (S715). An aroma having a waking effect is suitable for the third aroma in order to wake up a user, and may be menthol.

If the wake-up time has not arrived, the home server 170 repeats the operations from S703 to S715.

According to exemplary embodiments, the home server 170 can play predetermined music or sounds in order to wake up the user. For this purpose, the home server 170 can itself contain a sound system or can be connected to a sound system (not shown) so as to output predetermined music or sounds.

As explained above, the system of the invention can be constructed using a personal computer instead of the home server 170. In addition, when the system is embodied in computer software, it can be stored in a semiconductor memory element, ROM, flash memory, EEPROM, a floppy disk, an optical disc, a hard disk, in which the programs performing the functions of the home server 170 are loaded, or the like, as would be understood by one of skill in the art.

In this way, the operations of the sleeping environment control system may be performed according to sleeping stages.

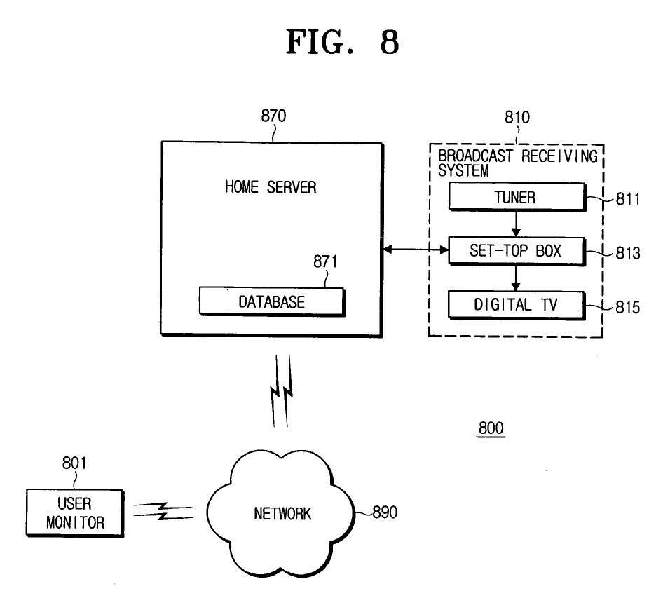

Hereafter, an exemplary broadcast information providing system according to the invention is explained with reference to FIG. 8.

FIG. 8 is a block diagram of a broadcast information providing system according to another exemplary embodiment of the invention.

Referring to FIG. 8, a broadcast receiving system 810 of the invention is connected to a home server 870 in a broadcast information providing system 800. In addition, a user monitor 801 is connected through a network 890. The network 890 and the user monitor 801 correspond to the network 190 and the health monitor 101 of FIG. 1.

The broadcast information providing system 800 determines a user's emotional state using the user's galvanic skin response and heart rate information received through the user monitor 801, and provides broadcast information to the digital television (TV) that the user is watching, based on the user's broadcast selection information and the user's state that is stored in the database.

The user monitor 801 classifies the user's emotional state within one of four stages using the user's galvanic skin responses and heart rate, and periodically transmits the classified state to the home server 870.

The user monitor 801 determines that the user's state is a waking state or a drowsy state by dividing the cases into those cases having a GN value equal to or smaller than 1.21 and those cases having a GN value larger than 1.21, as shown in Table 1. The GN value is calculated from the galvanic skin responses. Accordingly, the user monitor 801 can classify the user's emotional state into one of four stages as shown in Table 2.

TABLE 2

| Stage | Contents | GN value | Stress index |
|---|---|---|---|
| First stage | Waking with stress | GN value ≦1.21 | More than a |
| | | | predetermined |
| | | | value |
| Second stage | Waking without stress | GN value ≦1.21 | Less than a |
| | | | predetermined |
| | | | value |
| Third stage | Drowsy without stress | GN value >1.21 | Less than a |
| | | | predetermined |
| | | | value |
| Fourth stage | Drowsy with stress | GN value >1.21 | More than a |
| | | | predetermined |
| | | | value |

The broadcast receiving system 810 may receive a digital broadcast, and may comprise a tuner 811, a set-top box 813, and a digital TV 815. However, according to another exemplary embodiment, the tuner 811 and the set-top box 813 can be included in the home server 870.

The tuner 811 receives broadcast signals and transmits the signals to the set-top box 813. The broadcast signals are digital broadcast signals and include compressed audio and video signals, and Electric Program Guide (EPG) signals.

The EPG signals comprise broadcast program information including broadcast programs and descriptions. The descriptions are simple information related to each program, and are broadcast at the same time or after the time when the corresponding signals are transmitted.

The set-top box 813 decrypts the dynamic images received from the tuner 811 and transmits the images to the digital TV 815. In addition, the set-top box transmits EPG signals to the home server 870, and confirms the broadcast channel information, relating to the program that the user is currently watching, and transmits the information to the home server 870 based on a request of the home server 870.

Also, the set-top box 813 receives an EPG user interface (UI) for the user from the tuner 811 and inserts the EPG UI into the broadcast signals transmitted to the digital TV 815. The set-top box receives program information from the digital TV 815, the program having been selected by the user from the EPG UI displayed through the digital TV 815, and provides the broadcast signals of the channel broadcasting the corresponding program to the digital TV 815. The EPG UI displays the broadcast program information recommended by the home server 870 based on the user's emotional state, and is displayed on the digital TV through the set-top box 813.

The digital TV 815 displays the broadcast signals transmitted from the set-top box 813, displays the EPG UI transmitted from the set-top box 813, and transmits the information on the program that the user selects from watching the displayed EPG UI to the set-top box 813.

The home server 870 determines the user's emotional state from the user monitor 801 through the network 890, and, when the user is watching TV, provides broadcast information to the user so as to enable the user to select an appropriate broadcast program.

The home server 870 includes a database 871. However, the database 871 can be installed outside of the home server 870.

The database 871 stores users' preferred broadcast program information. The information is stored for more than a certain period of time according to the user's emotional state.

The home server 870 receives information on a user's emotional state from the user monitor 801 and receives EPG signals from the set-top box 813, and stores the received information in the database.

Upon receiving the information on the user's emotional state, the home server 870 requests information regarding the channel that the user is currently watching from the set-top box 813, and confirms the current broadcast program from the stored EPG signals based on the channel information.

The home server 870 receives the description of the corresponding broadcast program from the set-top box 813, and determines the genre of the corresponding broadcast program. The genre of the broadcast program determined in this way is called the P value. P values may include drama, movies, entertainment, shopping, sports, music, games, news, and the like, and may also be classified in more detail. An exemplary method by which the home server 810 determines the P value is explained below.

In the database, a home server 870 stores information regarding user identification, emotional state, time of storing, and P value of the broadcast currently being watched. In addition to storing such data, the home server 870 extracts a P value based on the data stored in the database 871. The extracted P value is the P value most preferred by the user when the user is in the corresponding emotional state. The home server 870 retrieves a broadcast matching the extracted P value through the EPG signals and creates an EPG UI, and transmits the created EPG UI to the set-top box 813. Optionally, if the program corresponding to the extracted P value does not exist within a certain time period from the current time, the EPG UI is not created.

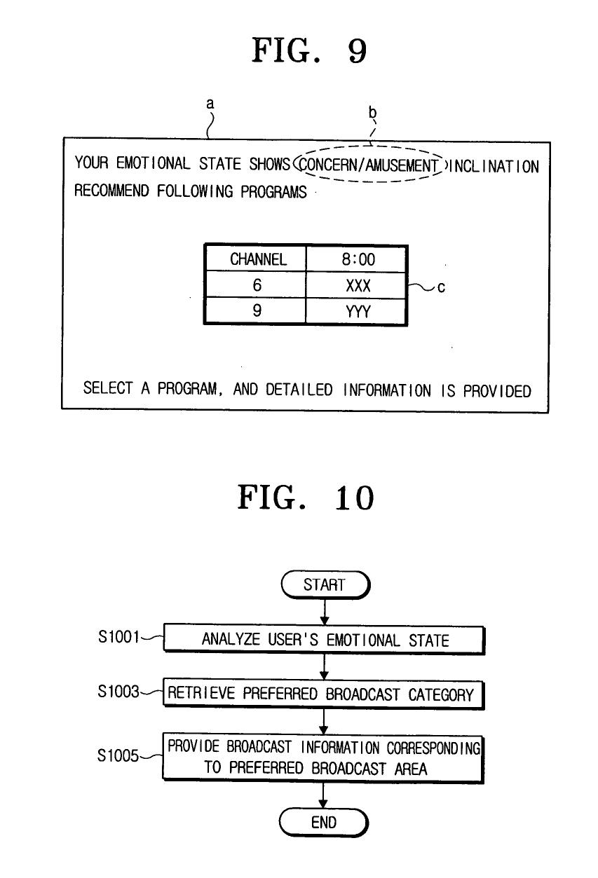

FIG. 9 shows an example of an EPG UI that can be displayed on a digital TV according to the broadcast information providing system depicted in FIG. 8.

Referring to FIG. 9, “a” is an EPG UI, and “b” is an indication of a user's emotional state corresponding to each stage. The exemplified “concern/amusement” is an example showing the second stage of a user's emotional state. “c” is a list of programs corresponding to the P value which a user prefers and which is extracted from the database 871 in a case where the user's emotional state is in the second stage. The displayed programs are being broadcasted currently or are to be broadcast in the future. The user can select the corresponding program in order to watch the broadcast.

Hereafter, an exemplary method by which the home server 870 determines the P value is explained.

The home server 870 can confirm the P value of the corresponding program based on the program currently being broadcast or based on the description in the EPG signal. The keyword table, where the keyword representing each P value is stored, is stored and updated, and the keyword is searched for in the descriptions of corresponding broadcast programs in order to obtain the corresponding P value. Table 3 is an example showing exemplary keywords related to each P value.

TABLE 3

| P value | Keyword |
|---|---|
| Sports | Sports, Baseball, Soccer, Basketball, Olympic Games, |
| | Major league, Asian Games . . . |
| Movies | Movie, Excellent film, Theater, Video |
| Drama | Drama, Soap opera, Mini series |
| News | News, Weather forecast, Anchor, Weather forecaster |
| Entertainment | Entertainment, Comedy, Gag, Talk show, Show . . . |
| Music | Music, Popular song |
| Shopping | Shopping, Shopping host |
| Games | Game . . . |
| . . . | . . . |

Hereafter, an exemplary broadcast information providing system 800 of the invention is explained using FIG. 10.

FIG. 10 is a flowchart explaining the operation of the broadcast information providing system according to an exemplary embodiment of the invention.

The user monitor 801 measures the galvanic skin responses and heart rate of a user, determines the corresponding emotional state of the user, and periodically transmits the determined emotional state to the home server 870 (S1001).

On receiving information of a user's emotional state from at least one user monitor 801, the home server 870 extracts the most preferred P value corresponding to the user's emotional state from the database 871. The home server 870 searches for an EPG UI, i.e. for a broadcast program corresponding to the extracted P value, in the EPG signals. For this purpose, the home server 870 searches in the description corresponding to each broadcast program in the EPG signal for the keywords in the keyword table of Table 3. In that way, the P value of each broadcast program is determined, and the home server then searches the EPG UI for the extracted P value.

In addition, the home server 870 stores the current user's emotional state and the P value of the broadcast program currently being watched in the database 871 (S1003).

The home server 870 transmits the EPG UI discovered in the search to the set-top box 813, and the set-top box 813 inserts the received EPG UI into the broadcast signals transmitted to the digital TV 815. The digital TV 815 displays the received EPG UI for the user, and waits for the selection of a broadcast program from the user S1005.

In this way, the broadcast information providing system 800 of the invention operates. The digital TV 815 receives the selection of a broadcast program from the user and transmits the corresponding broadcast information to the set-top box 813, so that the set-top box 813 can change the broadcast channel transmitted to the digital TV 815. Furthermore, the user can send a command directly to the set-top box 813 in order to change the channel.

As explained above, according to the invention, various systems in a home network can be controlled according to a user's sleeping state and emotional state based on the user's galvanic skin responses and heart rate information.

The optimum sleeping environments for each sleeping stage of a user may be analyzed, and home facilities can be controlled for the sleeping users based on the analyzed data.

Such controls of home facilities may be separately managed and stored in a database for at least one user based on the sleeping stage, thereby embodying the optimum sleeping environments for each user.

In addition, the sleeping environment control system of the invention removes the inconvenience to a user of wearing devices such as a brainwave measuring device in order to judge a user's sleeping stage and stress. By using the galvanic skin responses and the heart rate while sleeping, only simple devices can be worn on a wrist or an ankle, so that a user's sound sleep is not hindered.

Furthermore, a user's stress can be minimized by applying aromatherapy.

According to the broadcast information providing system, more comfortable and convenient environments for watching TV attentively in accordance with a user's emotional state are provided. In addition, by providing only predetermined information to users, users' objections to compulsory controls can be reduced.

The foregoing exemplary embodiments and advantages are merely exemplary and are not to be construed as limiting the present invention. The present teachings can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A home control system comprising:
a user monitor which periodically outputs user information of at least one user, the user information including a sleeping stage of the user and a stress index of the user;
a home server which receives and stores the user information in a database and generates a facility control command based on the user information stored in the database; and
a home facility system which receives the facility control command and controls an environment inside a home of the user based on the facility control command.

2. The home control system as claimed in claim 1, wherein the user monitor measures a galvanic skin response of the user and a heart rate of the user, determines the sleeping stage based on the galvanic skin response, and determines the stress index based on the heart rate.

3. The home control system as claimed in claim 2, further comprising:
a sensor system which outputs home state information to the home server, the home state information including at least one of a temperature, a humidity, and an illumination of an area inside the home; and
a network which connects the home server, the user monitor, the sensor system, and the home facility system.

4. The home control system as claimed in claim 3,
wherein the home server stores the home state information in correspondence with the user information in the database, creates a sleeping environment for each of a plurality of sleeping stages, and creates the facility control command based on the sleeping environments; and
wherein the home facility system controls at least one of a temperature, a humidity, and an illumination inside a home based on the facility control command.

5. The home control system as claimed in claim 3, wherein the network is a wireless local area network or a wireless personal area network.

6. The home control system as claimed in claim 4, wherein the home server calculates average values of the home state information in each sleeping stage and determines the sleeping environment for each sleeping stage based on the average value of the home state information, the average values being calculated in a case where the user information and the home state information is stored in the database for more than a certain period of time and the stress index is less than a predetermined value.

7. The home control system as claimed in claim 6, wherein the database stores control result information, including the sleeping stage, the stress index, the home state information, and a received time, together in a corresponding relationship.

8. The home control system as claimed in claim 7, wherein the average values are the averages of the temperature, the humidity, and the illumination of the control result information for which the stress index is less than a predetermined value, and wherein the control result information is extracted and sorted by sleeping stage.

9. The home control system as claimed in claim 6, wherein the facility control command is used to control the home facility system so that the home state information according to the sleeping stage becomes the average values.

10. The home control system as claimed in claim 9, wherein the facility control command is not changed so long as the sleeping stage is not changed.

11. The home control system as claimed in claim 6, wherein a ratio of the average value calculated for an initial certain period of time to the values measured after the initial certain period of time is calculated.

12. The home control system as claimed in claim 4, wherein a Heart Rate Variability (HRV) is measured from a maximum peak interval of an R wave or photoplethysmography (PPG), and the stress index is calculated by applying the HRV to a frequency conversion analysis.

13. The home control system as claimed in claim 3, wherein the sensor system comprises:
a sensor controller which is connected to the network, and outputs the home state information according to a request received from the home server; and
at least one sensor which measures at least one of the temperature, the humidity, and the illumination within the area, and outputs the measured temperature, humidity, or illumination to the sensor controller.

14. The home control system as claimed in claim 3, wherein the home facility system comprises:
an air conditioner which controls a temperature and a humidity of air in the area according to the facility control command;
at least one lighting facility which controls an illumination of the area according to the facility control command.

15. The home control system as claimed in claim 3, further comprising an aroma injector which injects aromas into the area according to an injection command from the home server, wherein the injection command is transmitted form the home server to the aroma injector if the stress index is more than a predetermined value.

16. The home control system as claimed in claim 15, wherein, if a user's predetermined wake-up time arrives, the home server transmits a command to the aroma injector for injecting an aroma having a stimulant composition.

17. A home control system comprising:
a user monitor which periodically outputs user information of at least one user, the user information indicating whether a user is in a waking state and a stress index of the user;
a home server which receives and stores the user information in a database and generates a facility control command based on the user information stored in the database; and
a home facility system which receives the facility control command and provides broadcast information to the user based on the facility control command.

18. The home control system as claimed in claim 17, wherein the user information includes an emotional state of the user,
wherein the user monitor measures a galvanic skin response of the user and a heart rate of the user, determines whether the user is in the waking state based on the galvanic skin response, determines the stress index based on the heart rate, and classifies the emotional state into one of a plurality of stages on the basis of whether the user is in the waking state and the stress index, and
wherein the home facility system provides at least one of digital television (TV) broadcast signals, information regarding the broadcast signals, image signals, and audio signals according to the facility control command.

19. The home control system as claimed in claim 18, wherein the home facility system includes:
a tuner which receives the digital TV broadcast signals including Electric Program Guide (EPG) signals;
a set-top box which outputs the EPG signals according to a request of the home server, receives a facility control command including an EPG user interface associated with a broadcast program recommended based on an emotional state of a user, and inserts the EPG user interface into the broadcast signals; and
a digital TV which displays the EPG user interface and the broadcast signals.

20. The home control system as claimed in claim 19, wherein the home server stores a genre of the broadcast program that the user is watching and the emotional state in the database at a time the emotional state is received, and
wherein the genre of the broadcast program is classified by searching text of a description of the broadcast program for keywords associated with each genre.

21. The home control system as claimed in claim 20, wherein the EPG user interface comprises information regarding the broadcast program, from among broadcast programs that are extracted from the EPG signals and to be broadcasted after the extraction, whose genre is identical to the genre of the broadcast program that is stored most in correspondence with the emotional state from amongst all the broadcast genres in the database.

22. The home control system as claimed in claim 21, wherein the digital TV receives a selection command for one of the broadcast programs included in the displayed EPG user interface, outputs corresponding selection information to the set-top box, and displays a broadcast program of a broadcast channel changed by the set-top box based on the selection information.

23. A home control method comprising:
periodically providing user information of at least one user, the user information including a sleeping stage of the user and a stress index of the user;
storing the user information in a database; and
generating a facility control command based on the user information stored in the database;
controlling an environment inside a home of the user based on the facility control command.

24. The home control method as claimed in claim 23, wherein the providing the user information comprises:
measuring a galvanic skin response of the user and a heart rate of the user;
determining the stress index based on the heart rate; and
determining the sleeping stage based on the galvanic skin response.

25. The home control method as claimed in claim 24, further comprising providing home state information including at least one of a temperature, a humidity, and an illumination of an area inside a home,
wherein the storing the user information comprises storing the home state information in correspondence with in the user information in the database on the basis of a received time, and
wherein generating the facility control command comprises creating a sleeping environment for each of a plurality of sleeping stages, and generating the facility control command based on the sleeping environments, and
wherein the controlling the environment comprising controlling at least one of a temperature, an humidity, and an illumination inside a home based on the facility control command.

26. The home control method as claimed in claim 25, wherein, in the controlling the environment, average values of the home state information in each sleeping stage is calculated, the average values being calculated in a case where the stress index is less than a predetermined value, and the sleep information and the home state information is stored in the database for more than a certain period of time, and the sleeping environment is judged.

27. The home control method as claimed in claim 25, wherein the database stores control result information including the sleeping stage, the stress index, the home state information, and a received time together in a corresponding relationship.

28. The home control method as claimed in claim 27, wherein the average values are the averages of the temperature, the humidity, and the illumination of the control result information for which the stress index is less than the predetermined value, and wherein the control result information is extracted from the control result information and sorted by the sleeping stage.

29. The home control method as claimed in claim 27, wherein the facility control command is used to control the environment so that the home state information according to the sleeping stage is made to be the average values.

30. The home control method as claimed in claim 29, wherein the facility control command is not changed so long as the sleeping stage is not changed.

31. The home control method as claimed in claim 26, wherein a ratio of the average values calculated for an initial certain period of time to the values measured after the initial certain period of time is calculated.

32. The home control method as claimed in claim 24, wherein a Heart Rate Variability (HRV) is measured from a maximum peak interval of an R wave or photoplethysmography (PPG), and the stress index is determined by applying the HRV to a frequency conversion analysis.

33. The home control method as claimed in claim 25, further comprising a injecting aromas into the user's sleeping space if the stress index is more than a predetermined value.

34. The home control method as claimed in claim 24, further comprising injecting an aroma having a stimulant composition when a predetermined wake-up time arrives.

35. A home control method comprising:
periodically providing user information of at least one user, the user information indicating whether a user is in a waking state and a stress index of the user;
storing the user information in a database; and
generating a facility control command based on user information stored in the database;
providing broadcast information to the user based on the facility control command.

36. The home control method as claimed in claim 35, wherein the user information includes an emotional state of the user,
wherein the providing the user information comprises:
measuring a galvanic skin response of the user and a heart rate of the user;
determines whether the user is in the waking state based on the galvanic skin response;
determining the stress index based on the heart rate; and
classifying the emotional state into one of a plurality of stages on the basis of whether the user is in the waking state and the stress index, and
wherein the providing the broadcast information comprises providing at least one of digital television (TV) broadcast signals, information regarding the broadcast signals, image signals, and audio signals according to the facility control command

37. The home control method as claimed in claim 35, wherein the providing the broadcast information comprises:
receiving the digital broadcast signals including Electric Program Guide (EPG) signals, including information on a program that is being broadcasted;
receiving the facility control command including an EPG user interface including information regarding a program which is recommended based on an emotional state of the user and inserting the EPG user interface into the broadcast signals; and
displaying the EPG user interface and image signals.

38. The home control method as claimed in claim 36, wherein, when the emotional state is provided, a genre of the broadcast that the user is watching and the emotional state are stored in the database in accordance with a receiving time of the emotional state.

39. The home control method as claimed in claim 38, wherein the genre of the broadcast is classified by searching a text of a description of the broadcast for keywords associated with each broadcast genre.

40. The home control method as claimed in claim 39, wherein the EPG user interface comprises information regarding the broadcast program from amongst the broadcast programs that are extracted from the EPG signals and to be broadcasted after the extraction, whose genre is identical to the genre of the broadcast program that is stored most in correspondence with the emotional state from amongst all the genres in the database.

41. The home control method as claimed in claim 40, wherein, in the displaying the EPG UI and the broadcast signals, a selection command is received for one of the broadcast programs included in the output EPG UI, and a broadcast program of a broadcast channel changed based on the selection information is displayed.
